(19) United States
(12) Patent Application Publication
(10) Pub. No.: US 2016/0237584 A1
(43) Pub. Date: Aug. 18, 2016

(54) ELECTROPLATING WITH REDUCED AIR BUBBLE DEFECTS

(71) Applicant: APPLIED Materials, Inc., Santa Clara, CA (US)

(72) Inventors: Paul R. McHugh, Kalispell, MT (US); Gregory J. Wilson, Kalispell, MT (US); John L. Klocke, Kalispell, MT (US); Randy A. Harris, Kalispell, MT (US); Bridger Hoerner, Columbia Falls, MT (US); Paul Van Valkenburg, Whitefish, MT (US)

(21) Appl. No.: 14/620,984

(22) Filed: Feb. 12, 2015

(51) Int. Cl. C25D 5/22; C25D 5/34; C25D 17/00; C25D 17/06; H01L 21/288; C25D 7/12

(52) U.S. Cl. CPC C25D 5/22; H01L 21/2885; C25D 7/12; C25D 17/004; C25D 17/001; C25D 17/06; C25D 5/34

(57) ABSTRACT

A method for processing a wafer includes holding the wafer in a face-up position with a seal ring contacting the wafer on a contact circumference. A bead of liquid is applied onto the entire contact circumference, with the bead of liquid contacting the wafer and the seal ring. The wafer is then inverted into a head-down position, lowered into contact with electrolyte and plated with a conductive film. Formation of the bead of liquid helps to displace air bubbles as the wafer is immersed into the electrolyte which reduces plating defects.

### BACKGROUND OF THE INVENTION

Manufacture of semiconductor integrated circuits and other micro-scale devices typically requires formation of multiple metal layers on a wafer or other substrate. By electroplating metals layers in combination with other steps, patterned metal layers forming the micro-scale devices are created. Electroplating is performed in an electroplating processor with the substrate in a bath of liquid electrolyte, and with electrical contacts of a contact ring touching a conductive layer on the substrate surface. Electrical current is passed through the electrolyte and the conductive layer. Metal ions in the electrolyte plate out onto the substrate, creating a metal film on the substrate. In some processors, the contact ring has a seal to keep the electrolyte away from the electrical contacts, to avoid build-up of plated metal on the contacts.

To avoid plating defects, it is important that the entire useable surface of the substrate be fully wetted by the electrolyte. Gas bubbles (typically air) on the substrate interfere with wetting the substrate surface. Various techniques have been proposed for avoiding gas bubbles, including controlled substrate entry trajectories into the electrolyte, rotating the substrate during entry into the electrolyte, and use of sonics. However, avoiding gas bubbles remains as a difficult engineering challenge in processing with a contact ring having a seal.

### SUMMARY OF THE INVENTION

In a first aspect, a method for processing a wafer includes holding the wafer in a contact ring having a seal and applying a bead of liquid directly from a liquid outlet onto the seal, with the bead of liquid contacting the wafer and the seal. The wafer is then moved into contact with an electrolyte and electroplated. The bead of liquid reduces defects caused by air bubbles on the wafer surface. The wafer may optionally be rotated while applying the bead of liquid. Generally, the liquid forming the bead is applied only directly from a supply tube to the contact circumference and without the liquid forming the bead contacting other surfaces of the wafer.

In a second aspect, a processor includes a vessel for holding an electrolyte and a rotor rotatably supported on a head, with a rotor motor in the head for rotating the rotor. A contact ring on the rotor has electrical contact fingers for making electrical contact with a conductive layer of a wafer held in the rotor. A seal on the contact ring to seals against the wafer. A liquid bead supply tube has an outlet for applying a bead of liquid onto the seal and the wafer.

In another aspect, a method for processing a wafer includes tilting the wafer to an angle of 1 to 5 degrees relative to a horizontal surface of electrolyte in a vessel, and then moving the wafer at from 125 to 300 mm/sec into the electrolyte. The wafer is then decelerated to a stop within 0.05 to 1.0 seconds, with a leading edge of the wafer below a meniscus level of the electrolyte sufficient to allow full wetting of an entire wafer down-facing surface. The wafer is returned to the flat horizontal position and then moved further down to a processing position in the electrolyte.

### BRIEF DESCRIPTION OF THE DRAWINGS

FIG. 1 is a schematic drawing of an electroplating processor in a head-down processing position.

FIG. 2 is a schematic drawing of the electroplating processor of FIG. 1 in a head-up load/unload position.

FIG. 3 is an enlarged perspective view of the contact ring as shown in FIG. 2.

FIG. 4 is a still further enlarged section view of the contact ring shown in FIG. 3.

### DETAILED DESCRIPTION

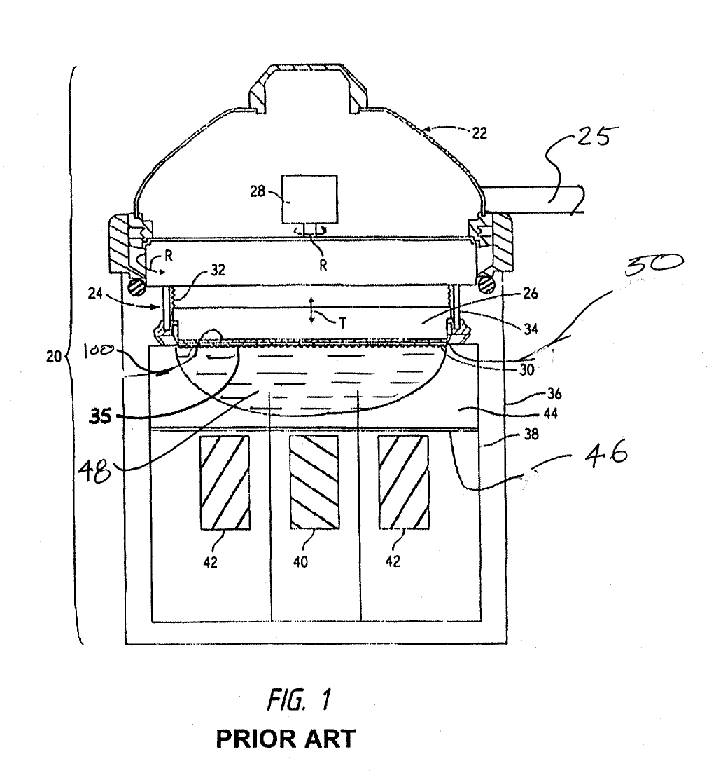

Turning now in detail to the drawings, as shown in FIG. 1, an electroplating processor 20 has a rotor 24 in a head 22. The head is supported on a lift/rotate mechanism 25, that can rotate the head 22 into a head-up position for loading and unloading a wafer, and to a head-down position for processing. The lift/rotate mechanism 25 can also lift and lower the head towards and away from a vessel 38 of the processor 20 holding a bath of electrolyte 48. The rotor 24 includes a backing plate 26 and a contact ring 30 having a seal ring 50. Contact ring actuators 34 move the contact ring 30 vertically (in the direction Tin FIG. 1), to engage the contact ring 30 and the seal ring 50 onto the down facing surface of a wafer or substrate 100. A bellows 32 may be used to seal internal components of the head.

The contact ring 30 typically has metal fingers 35 that contact a conductive seed layer on the wafer 100. The head 22 is positioned to place the substrate 50 into a bath of liquid electrolyte 48 held in the vessel 38 in a base 36, as shown in FIG. 1. One or more electrodes are in contact with the liquid electrolyte 48. FIG. 1 shows a design having a center electrode 40 surrounded by a single outer electrode 42, although multiple concentric outer electrodes may be used. An electric field shaping unit 44 made of a di-electric material may be positioned in the vessel between the electrodes and the wafer.

A membrane 46 may optionally be included, with anolyte in a lower chamber below the membrane and with catholyte in an upper chamber above the membrane 46. Electric current passes from the electrodes through the electrolyte 48 to a conductive surface on the wafer. A motor 28 in the head may be used to rotate the wafer during electroplating.

Turning to FIGS. 3-4, the seal ring 50 typically has an elastomer tip 52 which contacts and forms a seal against the wafer 100, with the tip 52 supported on, or part of, a rim 86 having a beam-like or cantilever structure. The annular surface of the wafer 100 that the seal ring 50 seals against is referred to as a seal contact circumference. The contact fingers 35, which are typically flexible metal elements, touch the wafer to the outside of the seal, so that they are not exposed to the electrolyte 48.

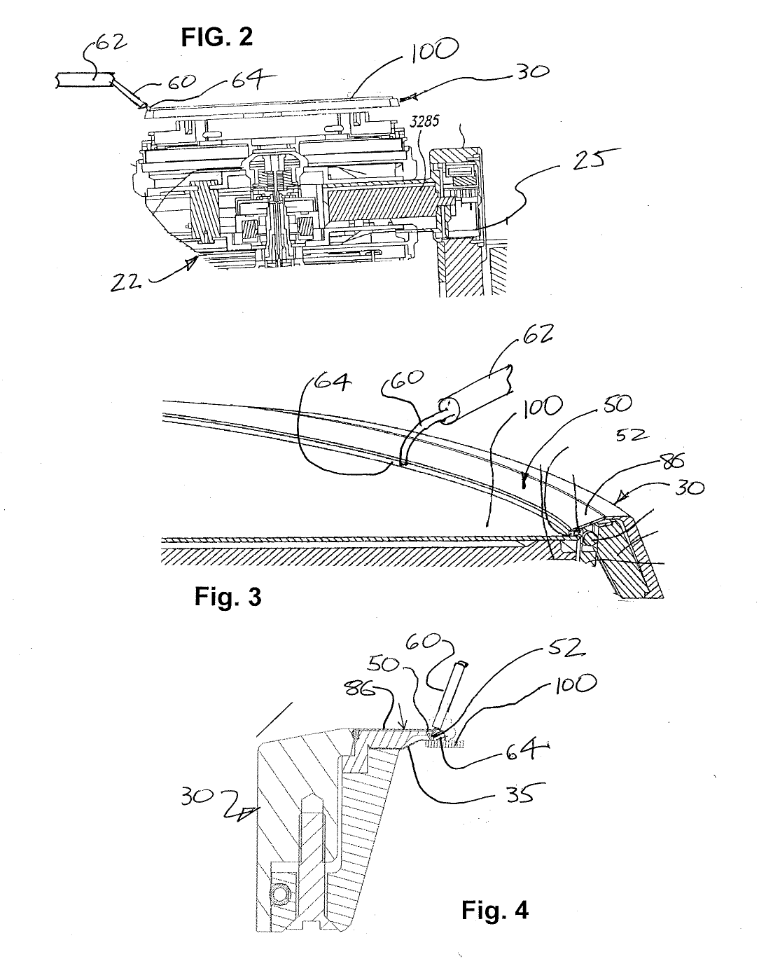

In use, the wafer 100 is clamped into the rotor 24, between the backing plate 26 and the contact ring 30, as shown in FIGS. 2-4. The head 22 is then inverted and moved down with the wafer 100 lowered into contact with the electrolyte 48. As this occurs, bubbles can be trapped along the interface between the contact ring 30 and wafer 100. The bubbles can migrate inwardly into the usable region of the wafer resulting in voids during the subsequent electroplating steps.

To reduce or prevent formation of bubbles, a small bead of liquid 64 may be applied along the circumferential interface between the seal ring 50 and the wafer 100, before the wafer 100 is moved into contact with the electrolyte 48. As shown in FIGS. 2-4, the bead of liquid 64 may be applied with the head 22 and the wafer 100 in the face up position, via a liquid supply tube 60 on a moving arm 62, such as a swing arm 62 supported on the processor 20. The moving arm 62 may retract after applying the bead of liquid 64, and before the head 22 is rotated into the head down position shown in FIG. 1. Using this technique, subsequent plating steps may be performed with bubble related defects on the wafer surface reduced or eliminated.

Alternatively, the moving arm 62 may be omitted, and the supply tube 60 is fixed in place on the processor. In this case, the lift/rotate mechanism 25 performs movements to properly position the contact ring 30 relative to the supply tube, to allow formation of the bead of liquid, and performs a flip or rotate movement from the head-up position of FIG. 2 into the head-down position of FIG. 1, while also clearing the supply tube.

Water, or in some cases electrolyte 48, may be used to form the bead of liquid 64. The bead of liquid 64 may be formed by slowly rotating the rotor 24 with the head 22 in the head-up position shown in FIG. 2. The bead of liquid 64 may have height generally matching the height of the vertical tip 52 of the seal ring, generally 1 to 3 mm. In most applications, the bead of liquid 64 has a largest characteristic dimension (i.e., dimension in any direction) of 1-5 mm.

The outlet or nozzle of the supply tube 60 may be positioned close to the seal ring 50, e.g., within 0.5 to 3 or 4 mm. The bead of liquid 64 is formed via direct application of the liquid in a laminar flow, without spraying or forming discrete droplets. The supply tube 60 may have an inside diameter or a round nozzle opening of 0.5 to 2.0 mm. As shown in FIG. 4, the supply tube 60 may be oriented at an acute angle to the wafer surface, and with the supply tube angled outwardly away from a center of the wafer.

When the head 22 is moved into the head-down position shown in FIG. 1, the bead of liquid 64 remains in place as the surface tension forces are greater than the gravitational forces acting on the bead of liquid. This method may be used with any plating application where the wafer 100 is not pre-wetted before plating. It is particularly useful for copper interconnect applications to eliminate bubbles on the leading edge of the wafer as the wafer is moved into the electrolyte 48. The dimensions of the liquid bead 64 may be controlled by the seal geometry near the wafer interface, the wetting angle of the seal material, and the surface tension of the applied liquid forming the bead

The processor 20 may be modified to allow formation of the bead of liquid with the head in the head-down position shown in FIG. 1. In this case the supply tube 60 applies the bead of liquid from below the wafer 100, rather than from above the wafer as shown in FIGS. 2-4. Hence, the bead of liquid may be used in processors where the head 22 or rotor 24 holding the wafer 100 does not rotate between head-up and head-down positions.

The bead of liquid 64 may be precisely placed along the seal interface with the wafer such that the corner or gap between the wafer 100 and the seal tip 52 is filled in. The bead of liquid 64 forces air out of the region between the seal tip 52 and the wafer surface, before the wafer 100 enters into the electrolyte 48. The bead of liquid 64 creates a hydraulic interface between the seal ring 50, or the seal tip 52 and the wafer 100. The bead of liquid 64 may also prevent unwanted de-ionized water or other liquid from filling the features across the entire wafer 100.

The bead of liquid 64 may advantageously be located outside of the useable die area of the wafer 100, or at least to a minimal distance such that exchange of the bead liquid 64 and the electrolyte 48 is minimized. Inward intrusion of the bead of liquid 64 onto the wafer may be minimal, as the bead 64 requires only a small volume of liquid and is confined and retained near the seal ring 50 via rotational motion. For example, a bead of liquid on a 300 mm diameter wafer 100 may be formed with only 2-8 or 3-5 ml of liquid.

The entry motion profile (i.e. speed, acceleration, angle, timing) of the wafer into the electrolyte 48 may be designed to minimize the amount of bubbles that are retained beneath the wafer 100 during entry. Computer simulations and high speed camera video of the wafer 100 entering into the electrolyte 48 (referred to as wafer entry) show air is trapped at the interface between the seal ring tip 52 and the wafer 100 during the initial phase of entry. If the trapped bubbles are not removed immediately, then as the wafer vertical entry motion stops, the bubbles may migrate upward along the tilted wafer surface towards the center of the wafer. Subsequent wafer motions (tilting flat and moving to the process position shown in FIG. 1) can further spread out the trapped bubbles.

Increasing the wafer entry speed may assist in quickly remove trapped bubbles at the interface where the seal ring tip 52 contacts the surface of the wafer 100. An entry speed of 177 mm/sec is generally sufficient to remove the initial trapped air. However, this entry speed, along with a deep plunge of the wafer 100 into the electrolyte 48 can cause significant electrolyte 48 displacement or splashing. The displaced electrolyte 48 may subsequently fall back into the vessel 38, entraining bubbles under the wafer 100.

This potential drawback may be reduced via a more shallow plunge, which reduces the amount of electrolyte 48 displacement. On the other hand, generally wafer entry is performed with the wafer at a slight tilt (e.g., 3° to the horizontal electrolyte surface). Using a wafer entry profile with a shallow plunge exposes the trailing edge of the wafer 100 (the high edge due to tilt) to de-wetting because it momentarily stays above the current meniscus level. The potential for de-wetting may be reduced by using a fast, shallow initial plunge to lessen the splash, but then quickly followed by a tilt to flat and a downward move to protect the trailing edge from de-wetting.

In summary, bubble defects may be reduced using a wafer entry motion as follows:

1. A fast initial wafer entry to shed the bubbles trapped at the seal/wafer interface at first entry. The fast entry may range from 125 or 177 mm/sec to 300 mm/sec. The wafer is tilted at an angle of 2-4°, and may optionally be rotated at 1-30 rpm.

2. A rapid deceleration to a stop with leading edge of the wafer 100 just far enough below meniscus level of the electrolyte 48 to allow full wetting of the entire wafer down-facing surface. The deceleration step may be performed within 0.05 to 1.0 seconds.

3. Start tilting the wafer 100 to the flat horizontal position and moving wafer downward soon enough to protect trailing edge of the wafer from de-wetting and/or air entrainment due to splashing electrolyte 48.

4. The wafer entry movement from initial contact with the electrolyte 48 until the wafer 100 is in the final processing position may be performed over an elapsed time of 1 or 0.5 to 0.1 seconds. The total move time from initial contact to the final processing position is typically 2 or 1 to 0.2 seconds. The wafer is typically moved down to a position where the bottom surface of the wafer is 3-10 mm below the surface of the electrolyte.

As used here, wafer means a substrate, for example a silicon wafer, on which microelectronic, micro-mechanical and/or micro-optical devices are formed.

Thus, novel apparatus and methods have been shown and described. Various changes and substitutions may of course be made, without departing from the spirit and scope of the invention. The invention, therefore, should not be limited except by the following claims and their equivalents.

1. A method for processing a wafer, comprising:
A] holding a wafer in a contact ring having a seal;
B] applying a bead of liquid directly from a liquid outlet onto the seal, with the bead of liquid contacting the wafer and the seal ring;
C] moving the wafer into contact with an electrolyte; and
D] conducting electrical current through the electrolyte and through a conductive layer on the wafer.

2. The method of claim 1 further including rotating the wafer while applying the bead of liquid, and with liquid forming the bead applied only directly from a supply tube to the contact circumference and without the liquid forming the bead contacting any other surface of the wafer.

3. The method of claim 1 with the bead of liquid having a largest characteristic dimension of 1-5 mm.

4. The method of claim 1 further comprising holding the wafer in a face-up position in step A], inverting the wafer into a head-down position after step B].

5. The method of claim 1 with the liquid outlet on a movable arm, and with the liquid outlet having an inside diameter of 0.5 to 2.0 mm.

6. The method of claim 4 with the liquid outlet oriented at an acute angle to the wafer surface.

7. The method of claim 6 with the liquid outlet angled outwardly away from a center of the wafer.

8. Processing apparatus comprising:
a vessel for holding an electrolyte;
a head supported on a lift/rotate mechanism;
a rotor rotatably supported on the head;
a rotor motor in the head for rotating the rotor;
a contact ring on the rotor having contact fingers for making electrical contact with a conductive layer of a wafer held in the rotor;
a seal on the contact ring adapted to seal against the wafer; and
a liquid bead supply tube having an outlet for applying a bead of liquid directly onto the seal and the wafer.

9. The apparatus of claim 8 with the supply position 0.5 to 2 mm apart from the seal.

10. The apparatus of claim 8 with the seal having a seal tip substantially perpendicular to the wafer surface and with the supply position within 0.5 to 2 mm of the seal tip.

11. The apparatus of claim 8 with the liquid bead supply tube on a movable arm.

12. The apparatus of claim 8 with the liquid bead supply tube oriented at an acute angle to the wafer surface and angled outwardly away from a center of the wafer.

13. A method for processing a wafer, comprising:
A] tilting wafer to an angle of 1 to 5 degrees relative to a horizontal surface of electrolyte in a vessel;
B] moving the wafer at from 125 to 300 mm/sec into the electrolyte;
C] decelerating the moving tilted wafer to a stop within 0.05 to 1.0 seconds, with a leading edge of the wafer below a meniscus level of the electrolyte sufficient to allow full wetting of an entire wafer down-facing surface;
D] returning the wafer to a flat horizontal position; and
E] moving the wafer further down to a processing position in the electrolyte.

14. The method of claim 13 wherein steps B] through E] are performed in 1 to 3 seconds.

15. The method of claim 13 wherein step B] is performed by moving the wafer linearly.

16. The method of claim 13 wherein step C] is performed within 0.05 to 0.1 seconds.

17. The method of claim 13 further including rotating the wafer.
